(19) United States
(12) Patent Application Publication
(10) Pub. No.: US 2014/0166245 A1
(43) Pub. Date: Jun. 19, 2014

(54) FLAT HEAT SPREADER AND METHOD FOR MANUFACTURING THE SAME

(71) Applicants: FURUI PRECISE COMPONENT (KUNSHAN) CO., LTD., (US); FOXCONN TECHNOLOGY CO., LTD., New Taipei (TW)

(72) Inventors: SHENG-LIANG DAI, Kunshan (CN); JIA-HONG WU, New Taipei (TW)

(73) Assignees: FOXCONN TECHNOLOGY CO., LTD., New Taipei (TW); FURUI PRECISE COMPONENT (KUNSHAN) CO., LTD., Kunshan (CN)

(21) Appl. No.: 13/864,295

(22) Filed: Apr. 17, 2013

(30) Foreign Application Priority Data
Dec. 14, 2012 (CN) 201210541408.0

(51) Int. Cl. H05K 7/20

(52) U.S. Cl. CPC H05K 7/20336
USPC 165/104.26; 29/890.032

(57) ABSTRACT

A flat heat spreader includes a hollow casing defining a vapor chamber therein, a working liquid contained in the vapor chamber, a first wick structure formed on an inner face of the casing, and a second wick structure formed on the inner face of the casing. The inner face of the casing includes a bottom face and a top face opposite to the bottom face. A porosity of the first wick structure is less than that of the second wick structure. A method for manufacturing the flat heat spreader is also provided.

### BACKGROUND

1. Technical Field

The present disclosure generally relates to heat dissipation devices, and particularly to a flat heat spreader having good heat transfer capability and a method for manufacturing the same.

2. Description of the Related Art

Electronic components, such as central processing units (CPUs) comprise numerous circuits operating at high speeds and generating substantial heat. Under most circumstances, it is necessary to cool the CPUs to maintain safe operating conditions and assure that the CPUs function properly and reliably. In the past, various approaches have been used to cool electronic components.

A heat spreader with a vapor chamber is usually used to help heat dissipation for electronic components. The heat spreader generally includes a base, a cover mounted on the base and a sealed chamber defined between the base and the cover. Moderate working liquid is contained in the chamber. The base has a wick structure spreading on the whole inner surface thereof, and the cover has a wick structure spreading on the whole inner surface thereof, too. During operation, the base absorbs heat from the electronic components, and the working liquid is heated into vapor in the chamber. The vapor flows towards the cover and dissipates the heat to the cover, then condenses into liquid and returns back to the base by the drive (i.e., capillary action) of the wick structures to continue a phase-change cycle.

However, different types of wick structures have different capability, e.g. sintered metal powders has good evaporating efficiency but large flow impedance to the working liquid; comparatively, metal mesh has less flow impedance but worse evaporating efficiency. This will adversely affect heat transfer efficiency of the heat spreader.

What is needed, therefore, is an improved flat heat spreader which overcomes the above described shortcomings.

### BRIEF DESCRIPTION OF THE DRAWINGS

FIG. 1 is a schematic, cross section view of a mandril of a method for manufacturing a flat heat spreader in accordance with a first embodiment of the present disclosure.

FIG. 2 is a schematic, cross section view of a mandril assembled with a tube of a method for manufacturing a flat heat spreader in accordance with a first embodiment of the present disclosure.

FIG. 3 is a schematic, cross section view of a pipe of a method for manufacturing a flat heat spreader in accordance with a first embodiment of the present disclosure.

FIG. 4 is a schematic, cross section view of a flat heat spreader of a method for manufacturing a flat heat spreader in accordance with a first embodiment of the present disclosure.

FIG. 5 is a schematic, cross section view of a mandril of a method for manufacturing a flat heat spreader in accordance with a second embodiment of the present disclosure.

FIG. 6 is a schematic, cross section view of a mandril assembled with a tube of a method for manufacturing a flat heat spreader in accordance with a second embodiment of the present disclosure.

FIG. 7 is a schematic, cross section view of a pipe of a method for manufacturing a flat heat spreader in accordance with a second embodiment of the present disclosure.

FIG. 8 is a schematic, cross section view of a flat heat spreader of a method for manufacturing a flat heat spreader in accordance with a second embodiment of the present disclosure.

FIG. 9 is a schematic, cross section view of a mandril of a method for manufacturing a flat heat spreader in accordance with a third embodiment of the present disclosure.

FIG. 10 is a schematic, cross section view of a mandril assembled with a tube of a method for manufacturing a flat heat spreader in accordance with a third embodiment of the present disclosure.

FIG. 11 is a schematic, cross section view of a pipe of a method for manufacturing a flat heat spreader in accordance with a third embodiment of the present disclosure.

FIG. 12 is a schematic, cross section view of a flat heat spreader of a method for manufacturing a flat heat spreader in accordance with a third embodiment of the present disclosure.

### DETAILED DESCRIPTION

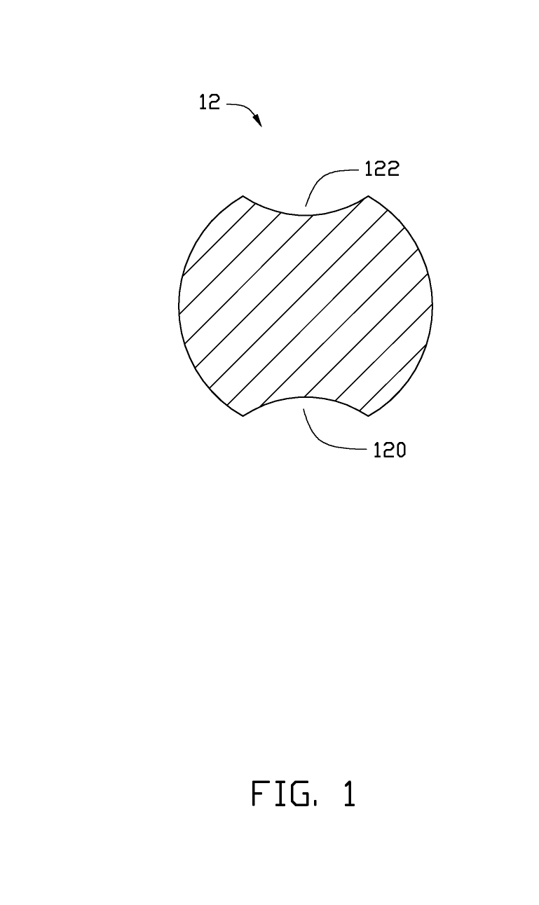

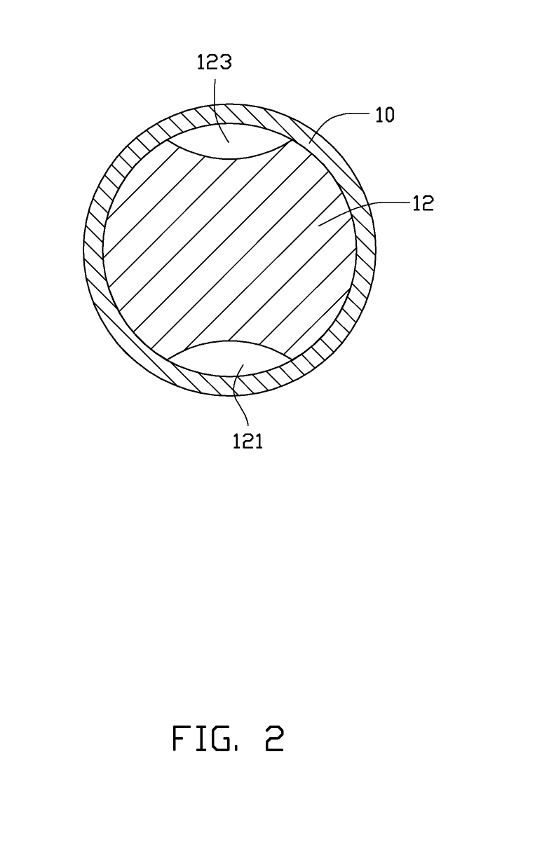

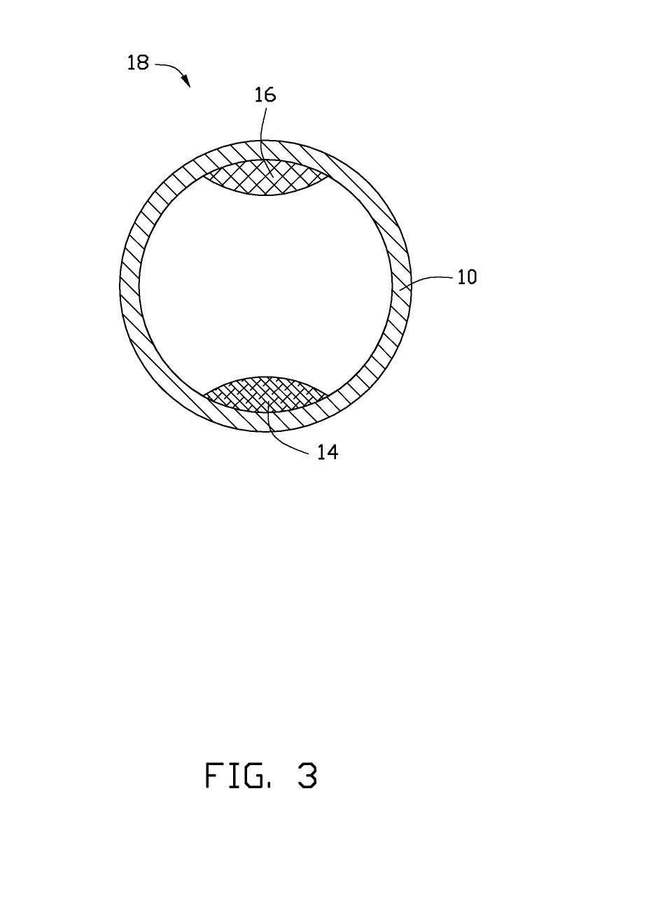

Referring to FIGS. 1-4, a method for manufacturing a flat heat spreader 1000 in accordance with a first embodiment of the disclosure includes steps described below.

Step 1, an elongated hollow tube 10 is provided. The tube 10 is made of metal, such as copper.

Step 2, a solid mandril 12 is provided. The mandril 12 is made of metal, such as heat-resistant alloy. The mandril 12 is elongated and substantially cylinder. A diameter of the mandril 12 is equal to an inner diameter of the tube 10. An elongated first groove 120 is defined on an outer periphery of the mandril 12. The first groove 120 extends along an axis of the mandril 12. An elongated second groove 122 is defined on the outer periphery of the mandril 12 opposite to the first groove 120. The second groove 122 extends along the axis of the mandril 12.

Step 3, the mandril 12 is inserted into the tube 10, and the outer periphery of the mandril 12 is fitly attached to an inner peripheral face of the tube 10. A first receiving portion 121 is defined between the tube 10 and the mandril 12 corresponding to the first groove 120. A second receiving portion 123 is defined between the tube 10 and the mandril 12 corresponding to the second groove 122.

Step 4, a plurality of metal powders are provided. The metal powders are filled into the first receiving portion 121. The metal powders received in the first receiving portion 121 are sintered to form a first wick structure 14 on the inner peripheral face of the tube 10.

Step 5, a second wick structure 16 is formed in the second receiving portion 123 and on the inner peripheral face of the tube 10. The second wick structure 16 is selected from metal mesh, carbon nanotube array or bundle of fibers.

Step 6, the mandril 12 is pulled out of the tube 10, whereby a pipe 18 is obtained.

Step 7, the pipe 18 is flattened along a direction extending from the first wick structure 14 to the second wick structure 16. A few moderate working liquid 17, such as water, alcohol, or paraffin, are injected into the flattened pipe 18, and then the flattened pipe 18 is vacuumized and sealed, whereby the flat heat spreader 1000 is obtained. The first wick structure 14 abuts against the second wick structure 16.

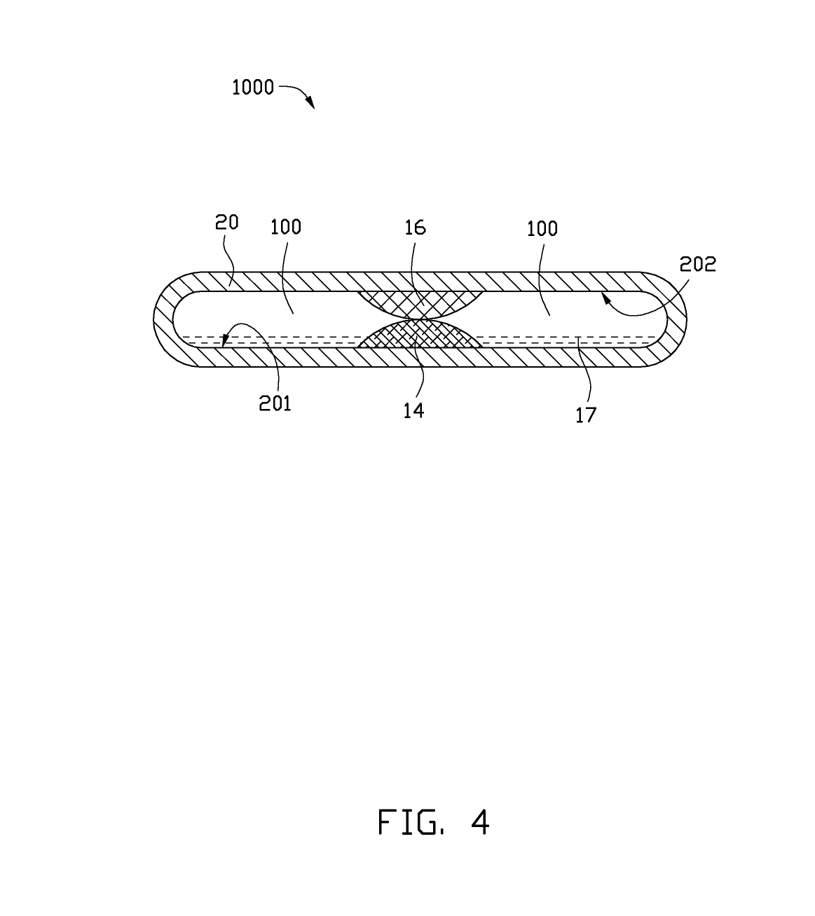

Referring to FIG. 4 again, the flat heat spreader 1000 includes a hollow casing 20 which defines a vapor chamber 100 therein, a first wick structure 14 and a second wick structure 16 formed on an inner face of the casing 20, and working liquid 17 contained in the vapor chamber 100. A cross section of the casing 20 has a shape like a capsule. The inner face of the casing 20 includes a bottom face 201 and a top face 202 opposite to the bottom face 201. The first wick structure 14 is formed on the bottom face 201. The second wick structure 16 is formed on the top face 202. The second wick structure 16 is located above the first wick structure 14. The second wick structure 16 abuts against the first wick structure 14. The first wick structure 14 has a cross section in a shape of arc. The second wick structure has a cross section in a shape of arc. The second wick structure 16 is tangent to the first wick structure 14 at a straight line between the bottom face 201 and the top face 202. The first wick structure 14 is formed from sintered metal powders. The second wick structure 16 is selected from metal mesh, carbon nanotube array or bundle of fibers. A porosity of the first wick structure 14 is less than that of the second wick structure 16.

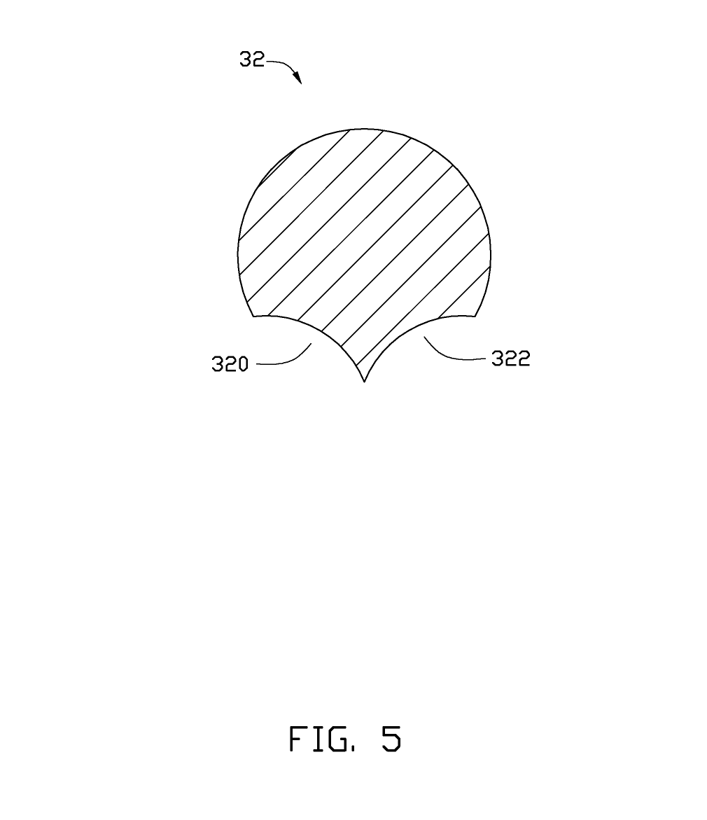

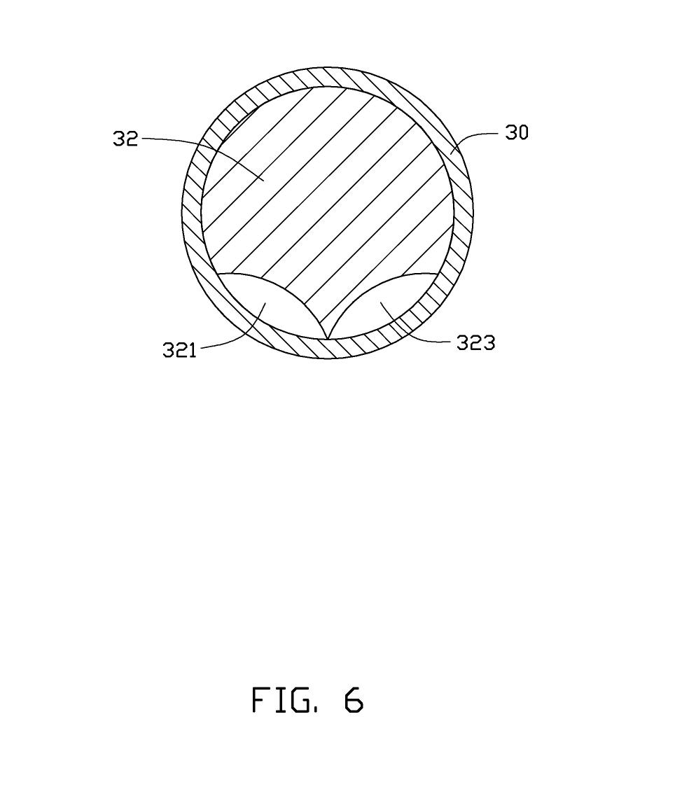

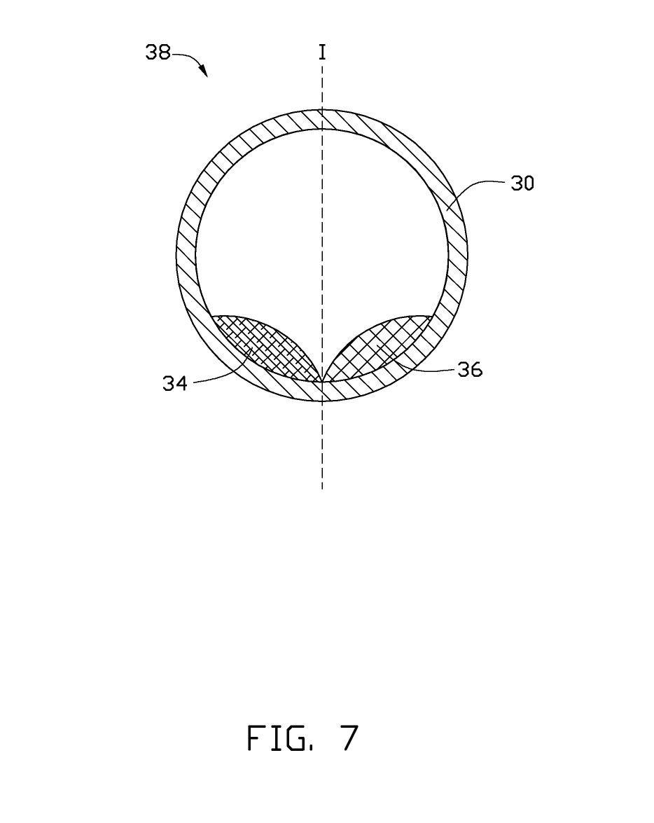

Referring to FIGS. 5-8, a method for manufacturing a flat heat spreader 2000 in accordance with a second embodiment of the disclosure includes steps described below.

Step 1, an elongated hollow tube 30 is provided. The tube 30 is made of metal, such as copper.

Step 2, a solid mandril 32 is provided. The mandril 32 is made of metal, such as heat-resistant alloy. The mandril 32 is elongated and substantially cylinder. A diameter of the mandril 32 is equal to an inner diameter of the tube 30. An elongated first groove 320 is defined on an outer periphery of the mandril 32. The first groove 320 extends along an axis of the mandril 32. An elongated second groove 322 is defined on the outer periphery of the mandril 32 adjacent to the first groove 320. The second groove 322 extends along the axis of the mandril 32.

Step 3, the mandril 32 is inserted into the tube 30, and the outer periphery of the mandril 32 is fitly attached to an inner peripheral face of the tube 30. A first receiving portion 321 is defined between the tube 30 and the mandril 32 corresponding to the first groove 320. A second receiving portion 323 is defined between the tube 30 and the mandril 32 corresponding to the second groove 322.

Step 4, a plurality of metal powders are provided. The metal powders are filled into the first receiving portion 321. The metal powders received in the first receiving portion 321 are sintered to form a first wick structure 34 on the inner peripheral face of the tube 30.

Step 5, a second wick structure 36 is formed in the second receiving portion 323 and on the inner peripheral face of the tube 30. The second wick structure 36 is selected from metal mesh, carbon nanotube array or bundle of fibers.

Step 6, the mandril 32 is pulled out of the tube 30, whereby a pipe 38 is obtained.

Step 7, the pipe 38 is flattened along a middle line I defined between the first wick structure 34 and the second wick structure 36. A few moderate working liquid 37, such as water, alcohol, or paraffin, are injected into the flattened pipe 38, and then the flattened pipe 38 is vacuumized and sealed, whereby the flat heat spreader 2000 is obtained. The first wick structure 34 and the second wick structure 36 are abreast.

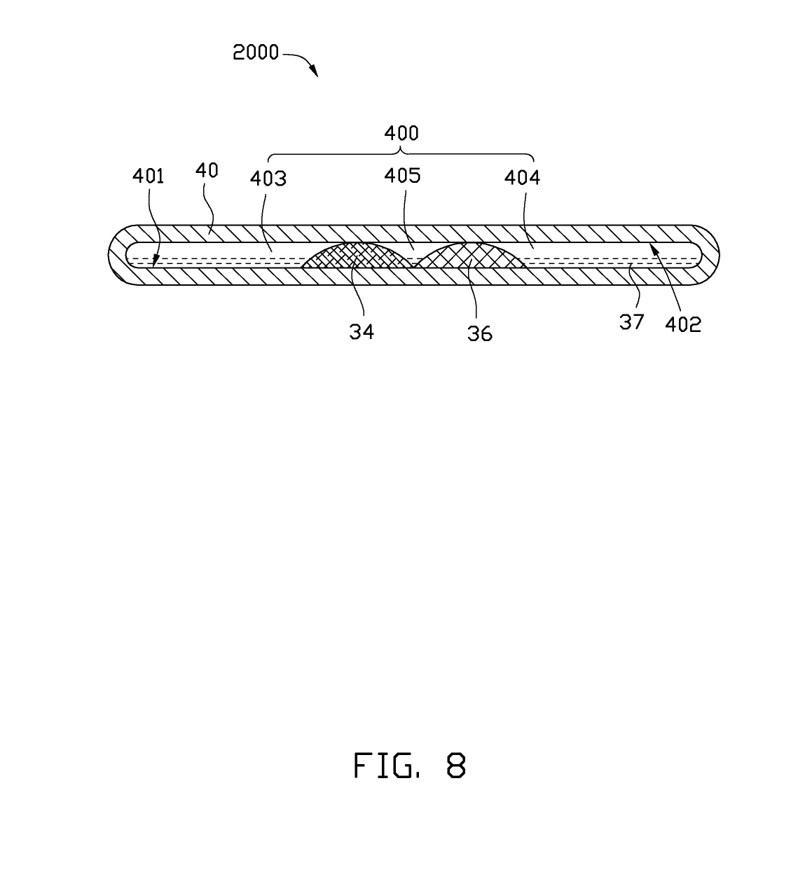

Referring to FIG. 8 again, the flat heat spreader 2000 includes a hollow casing 40 which defines a vapor chamber 400 therein, a first wick structure 34 and a second wick structure 36 formed on an inner face of the casing 40, and working liquid 37 contained in the vapor chamber 400. A cross section of the casing 40 has a shape like a capsule. The inner face of the casing 40 includes a bottom face 401 and a top face 402 opposite to the bottom face 401. The first wick structure 34 and the second wick structure 36 are formed on the bottom face 401. The first wick structure 34 and the second wick structure 36 are abreast. The first wick structure 34 has a cross section in a shape of arc. The second wick structure 36 has a cross section in a shape of arc. The second wick structure 36 intersects with the first wick structure 34 at a straight line on the bottom face 401. The top face 402 abuts against the first wick structure 34 and the second wick structure 36. The first wick structure 34 is formed from sintered metal powders. The second wick structure 36 is selected from metal mesh, carbon nanotube array or bundle of fibers. A porosity of the first wick structure 34 is less than that of the second wick structure 36.

The vapor chamber 400 comprises a first chamber 403, a second chamber 404 and a third chamber 405. The first chamber 403, the second chamber 404 and the third chamber 405 are spaced from each other. The first chamber 403 is defined between the inner face of the casing 40 and the first wick structure 34. The second chamber 404 is defined between the inner face of the casing 40 and the second wick structure 36. The third chamber 405 is defined among the inner face of the casing 40, the first wick structure 34 and the second wick structure 36.

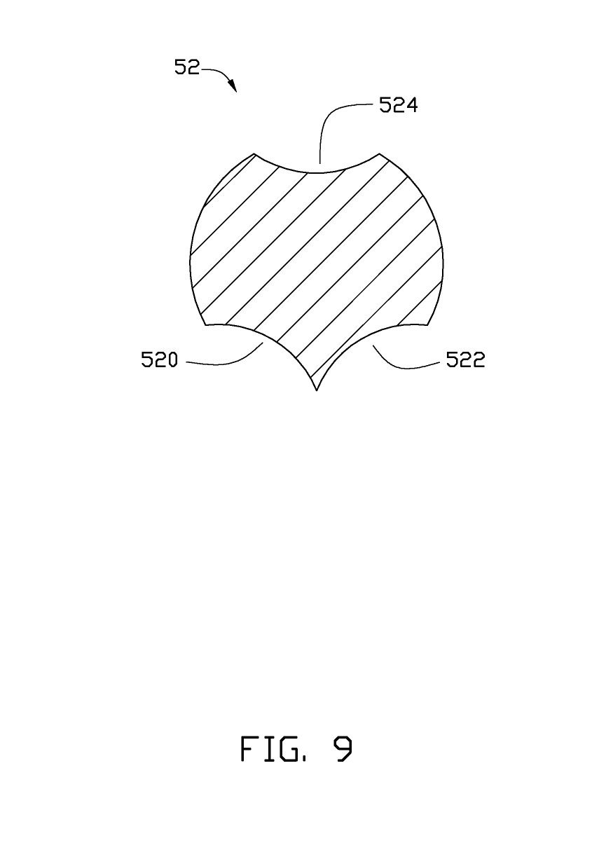

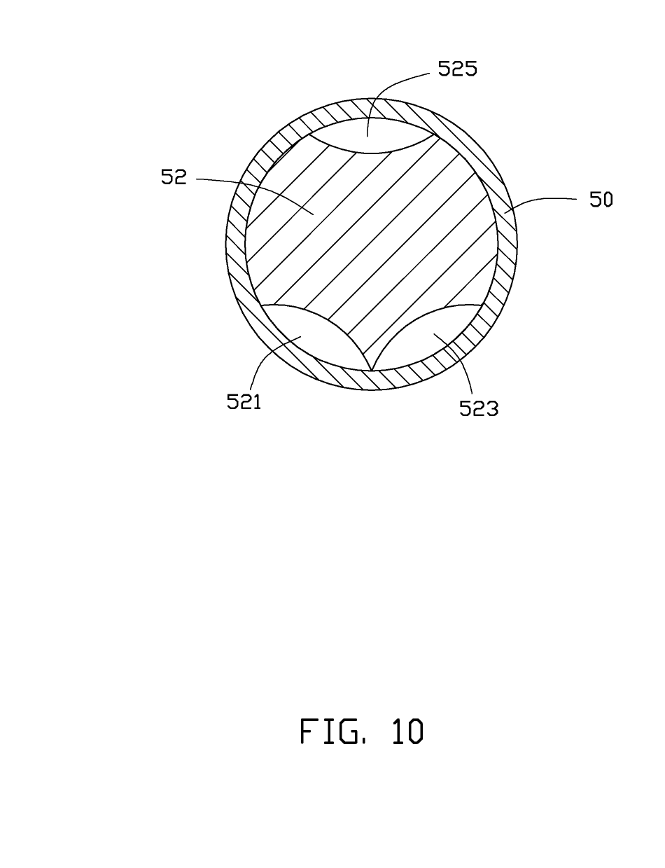

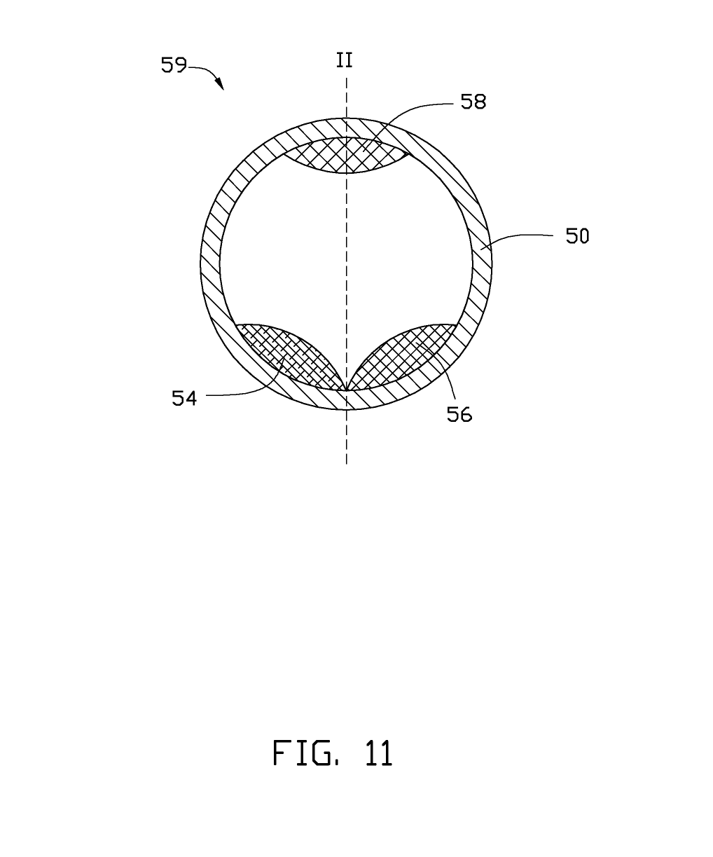

Referring to FIGS. 9-12, a method for manufacturing a flat heat spreader 3000 in accordance with a third embodiment of the disclosure includes steps described below.

Step 1, an elongated hollow tube 50 is provided. The tube 50 is made of metal, such as copper.

Step 2, a solid mandril 52 is provided. The mandril 52 is made of metal, such as heat-resistant alloy. The mandril 52 is elongated and substantially cylinder. A diameter of the mandril 52 is equal to an inner diameter of the tube 50. An elongated first groove 520 is defined on an outer periphery of the mandril 52. The first groove 520 extends along an axis of the mandril 52. An elongated second groove 522 is defined on the outer periphery of the mandril 52 adjacent to the first groove 520. The second groove 522 extends along the axis of the mandril 52. An elongated third groove 524 is defined on the outer periphery of the mandril 52 opposite to the first and second grooves 520, 522. The third groove 524 extends along the axis of the mandril 52.

Step 3, the mandril 52 is inserted into the tube 50, and the outer periphery of the mandril 52 is fitly attached to an inner peripheral face of the tube 50. A first receiving portion 521 is defined between the tube 50 and the mandril 52 corresponding to the first groove 520. A second receiving portion 523 is defined between the tube 50 and the mandril 52 corresponding to the second groove 522. A third receiving portion 525 is defined between the tube 50 and the mandril 52 corresponding to the third groove 524.

Step 4, a plurality of metal powders are provided. The metal powders are filled into the first receiving portion 521. The metal powders received in the first receiving portion 521 are sintered to form a first wick structure 54 on the inner peripheral face of the tube 50.

Step 5, a second wick structure 56 is formed in the second receiving portion 523 and on the inner peripheral face of the tube 50. The second wick structure 56 is selected from metal mesh, carbon nanotube array or bundle of fibers.

Step 6, a third wick structure 58 is formed in the third receiving portion 525 and on the inner peripheral face of the tube 50. The third wick structure 58 is selected from metal mesh, carbon nanotube array or bundle of fibers.

Step 7, the mandril 52 is pulled out of the tube 50, whereby a pipe 59 is obtained.

Step 8, the pipe 59 is flattened along a middle line II defined between the first wick structure 54 and the second wick structure 56. A few moderate working liquid 57, such as water, alcohol, or paraffin, are injected into the flattened pipe 59, and then the flattened pipe 59 is vacuumized and sealed, whereby the flat heat spreader 3000 is obtained. The first wick structure 54 and the second wick structure 36 are abreast. The third wick structure 58 is located above the first and second wick structures 56, 58. The third wick structure 58 abuts against the first and second wick structures 56, 58.

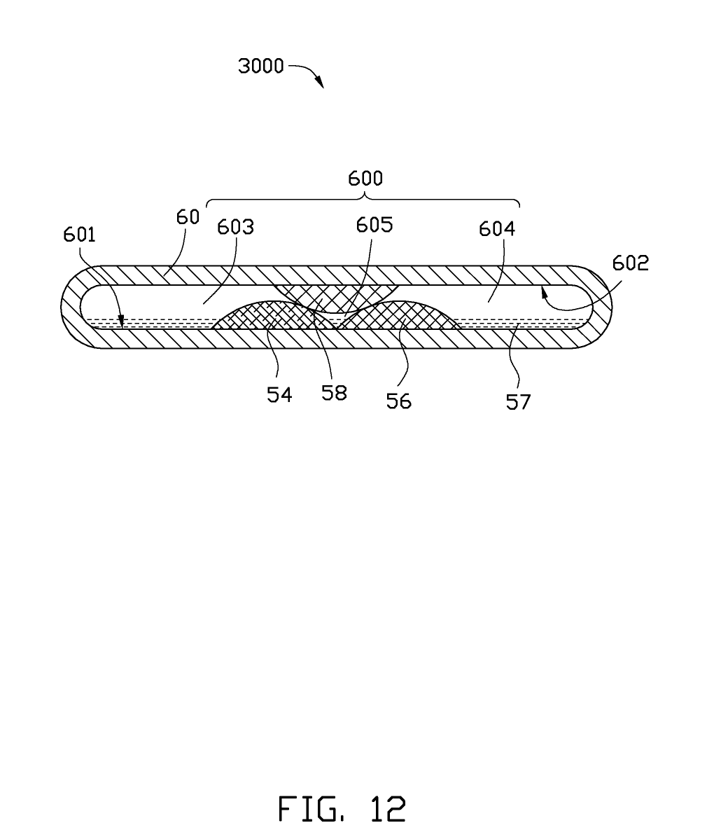

Referring to FIG. 12 again, the flat heat spreader 3000 includes a hollow casing 60 which defines a vapor chamber 600 therein, a first wick structure 54 formed on an inner face of the casing 60, a second wick structure 56 formed on the inner face of the casing 60, a third wick structure 58 formed on the inner face of the casing 60, and working liquid 57 contained in the vapor chamber 600. A cross section of the casing 60 has a shape like a capsule. The inner face of the casing 60 includes a bottom face 601 and a top face 602 opposite to the bottom face 601.

The first wick structure 54 and the second wick structure 56 are formed on the bottom face 601 and away from the top face 602 to respectively define a gap between the first wick structure 54, the second wick structure 56 and the top face 602. The third wick structure 58 is formed on the top face 602 and away from the bottom face 601 to define a gap between the third wick structure 58 and the bottom face 601. The first wick structure 54 and the second wick structure 56 are abreast. The third wick structure 58 is located above the first and second wick structures 54, 56. The third wick structure 58 abuts against the first and second wick structures 54, 56. The first wick structure 54 has a cross section in a shape of arc. The second wick structure 56 has a cross section in a shape of arc. The third wick structure 58 has a third section in a shape of arc. The third wick structure 58 is tangent to the first wick structure 14 at a first straight line between the bottom face 601 and the top face 602. The third wick structure 58 is tangent to the second wick structure 56 at a second straight line between the bottom face 601 and the top face 602. The second wick structure 56 intersects with the first wick structure 54 at a third straight line on the bottom face 601. The first wick structure 54 is formed from sintered metal powders. The second wick structure 56 is selected from metal mesh, carbon nanotube array or bundle of fibers. The third wick structure 58 is selected from metal mesh, carbon nanotube array or bundle of fibers. A porosity of the first wick structure 54 is less than that of the second wick structure 56. A porosity of the second wick structure 56 is less than that of the third wick structure 58.

The vapor chamber 600 comprises a first chamber 603, a second chamber 604 and a third chamber 605. The first chamber 603, the second chamber 604 and the third chamber 605 are spaced from each other. The first chamber 603 is defined among the inner face of the casing 60, the first wick structure 54 and the third wick structure 58. The second chamber 604 is defined among the inner face of the casing 60, the second wick structure 56 and the third wick structure 58. The third chamber 605 is defined among the first wick structure 54, the second wick structure 56 and the third wick structure 58.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method for manufacturing a flat spreader comprising:
Step 1, providing an elongated hollow tube;
Step 2, providing a solid mandril, wherein the mandril is elongated and cylinder, a diameter of the mandril is equal to an inner diameter of the tube, an elongated first groove is defined on an outer periphery of the mandril and extends along an axis of the mandril, and an elongated second groove is defined on the outer periphery of the mandril and extends along the axis of the mandril;
Step 3, inserting the mandril into the tube, wherein a first receiving portion is defined between the tube and the mandril corresponding to the first groove, and a second receiving portion is defined between the tube and the mandril corresponding to the second groove;
step 4, providing a plurality of metal powders, wherein the metal powders are filled into the first receiving portion, and the metal powders are sintered to form a first wick structure on an inner peripheral face of the tube;
step 5, forming a second wick structure in the second receiving portion and on the inner peripheral face of the tube;
step 6, pulling the mandril out of the tube, and obtaining a pipe with the first and second wick structures; and
step 7, flattening the pipe, injecting working liquid into the flattened pipe, and then vacuumizing and sealing the flattened pipe to obtain a flat heat spreader.

2. The method as claimed in claim 1, wherein a porosity of the first wick structure is less than that of the second wick structure.

3. The method as claimed in claim 1, wherein in step 2, the first groove is opposite to the second groove.

4. The method as claimed in claim 3, wherein in step 7, the pipe is flattened along a direction extending from the first wick structure to the second wick structure.

5. The method as claimed in claim 4, wherein in step 7, after the pipe is flattened, the second wick structure is located above and abuts against the first wick structure.

6. The method as claimed in claim 4, wherein the second wick structure is tangent to the first wick structure at a straight line.

7. The method as claimed in claim 1, the first groove is adjacent to the second groove.

8. The method as claimed in claim 7, wherein in step 7, the pipe is flattened along a middle line I defined between the first wick structure and the second wick structure.

9. The method as claimed in claim 8, wherein in step 7, after the pipe is flattened, the first wick structure and the second wick structure are abreast, and an inner face of the flattened pipe abuts against the first wick structure and the second wick structure.

10. The method as claimed in claim 9, wherein The second wick structure intersects with the first wick structure at a straight line.

11. A flat heat spreader comprising:
a hollow casing defining a vapor chamber therein;
a working liquid contained in the vapor chamber;
a first wick structure formed on an inner face of the casing, and the inner face of the casing comprising a bottom face and a top face opposite to the bottom face; and
a second wick structure formed on the inner face of the casing, the second wick structure being tangent to or intersecting with the first wick structure;
wherein a porosity of the first wick structure is less than that of the second wick structure.

12. The flat heat spreader as claimed in claim 11, wherein the second wick structure is formed on the top face, the first wick structure is formed on the bottom face, and the second wick structure is located above and abuts against the first wick structure.

13. The flat heat spreader as claimed in claim 11, wherein the first wick structure and the second wick structure are formed on the bottom face, the first wick structure and the second wick structure are abreast, and an inner face of the flattened pipe abuts against the first wick structure and the second wick structure.

14. The flat heat spreader as claimed in claim 13, wherein the vapor chamber comprises a first chamber defined between the inner face of the casing and the first wick structure, a second chamber defined between the inner face of the casing and the second wick structure, and a third chamber defined among the inner face of the casing, the first wick structure and the second wick structure, and the first chamber, the second chamber and the third chamber are spaced from each other.

15. The flat heat spreader as claimed in claim 13, further comprising a third wick structure formed on the inner face of the casing, and a porosity of the second wick structure is less than that of the third wick structure.

16. The flat heat spreader as claimed in claim 15, the third wick structure is formed on the top face, and the third wick structure is located above and abuts against the first and second wick structures.

17. The flat heat spreader as claimed in claim 16, wherein the vapor chamber comprises a first chamber defined among the inner face of the casing, the first wick structure and the third wick structure, a second chamber defined among the inner face of the casing, the second wick structure and the third wick structure, and a third chamber defined among the first wick structure, the second wick structure and the third wick structure, and the first chamber, the second chamber and the third chamber are spaced from each other.

18. A method for manufacturing a flat spreader comprising:
Step 1, providing an elongated hollow tube;
Step 2, providing a solid mandril, wherein the mandril is elongated and cylinder, a diameter of the mandril is equal to an inner diameter of the tube, an elongated first groove is defined on an outer periphery of the mandril and extends along an axis of the mandril, an elongated second groove is defined on the outer periphery of the mandril adjacent to the first groove and extends along the axis of the mandril, and an elongated third groove is defined on the outer periphery of the mandril opposite to the first and second grooves and extends along the axis of the mandril;
Step 3, inserting the mandril into the tube, wherein a first receiving portion is defined between the tube and the mandril corresponding to the first groove, a second receiving portion is defined between the tube and the mandril corresponding to the second groove, and a third receiving portion is defined between the tube and the mandril corresponding to the third groove;
step 4, providing a plurality of metal powders, wherein the metal powders are filled into the first receiving portion, and the metal powders are sintered to form a first wick structure on an inner peripheral face of the tube;
step 5, forming a second wick structure in the second receiving portion and on the inner peripheral face of the tube;
step 6, forming a third wick structure in the third receiving portion and on the inner peripheral face of the tube;
step 7, pulling the mandril out of the tube, and obtaining a pipe with the first, second and third wick structures; and
step 8, flattening the pipe along a middle line defined between the first wick structure and the second wick structure, injecting working liquid into the flattened pipe, and then vacuumizing and sealing the flattened pipe to obtain a flat heat spreader.

19. The method as claimed in claim 16, wherein a porosity of the second wick structure is less than that of the third wick structure.

20. The method as claimed in claim 19, wherein in step 7, after the pipe is flattened, the third wick structure is located above and abuts against the first wick structure and the second wick structure.
